(19) United States
(12) Patent Application Publication
(10) Pub. No.: US 2024/0107766 A1
(43) Pub. Date: Mar. 28, 2024

(54) SEMICONDUCTOR DEVICE AND METHOD OF MANUFACTURING THE SAME

(71) Applicant: Kioxia Corporation, Tokyo (JP)

(72) Inventors: Eri SAHARA, Nagoya (JP); Ai OMODAKA, Yokkaichi (JP)

(73) Assignee: Kioxia Corporation, Tokyo (JP)

(21) Appl. No.: 18/461,232

(22) Filed: Sep. 5, 2023

(30) Foreign Application Priority Data
Sep. 20, 2022 (JP) 2022-149502
Jun. 20, 2023 (JP) 2023-101227

(51) Int. Cl. H10B 43/27; H10B 41/10; H10B 41/27; H10B 43/10

(52) U.S. Cl. CPC H10B 43/27; H10B 41/10; H10B 41/27; H10B 43/10

(57) ABSTRACT

In one embodiment, a semiconductor device includes a stacked film including a plurality of first insulators and a plurality of electrode layers that are alternately stacked in a first direction. The device includes a first plug provided on a first electrode layer among the plurality of electrode layers, and having a tube shape extending in the first direction. The device includes a second insulator provided in the first plug and the first electrode layer, and having a columnar shape extending in the first direction. Furthermore, a diameter of a side face of the first plug enclosing the second insulator is larger than a diameter of a side face of the first electrode layer enclosing the second insulator.

### CROSS-REFERENCE TO RELATED APPLICATIONS

This application is based upon and claims the benefit of priority from the prior Japanese Patent Applications No. 2022-149502, filed on Sep. 20, 2022 and No. 2023-101227, filed on Jun. 20, 2023, the entire contents of which are incorporated herein by reference.

### FIELD

Embodiments described herein relate to a semiconductor device and a method of manufacturing the same.

### BACKGROUND

In forming a step structure portion including electrode layers and disposing a contact plug on one of the electrode layers, the contact plug is potentially short-circuited with another electrode layer.

### BRIEF DESCRIPTION OF THE DRAWINGS

FIG. 1 is a cross-sectional view illustrating the structure of a semiconductor device of a first embodiment;

FIG. 2 is an enlarged cross-sectional view illustrating the structure of the semiconductor device of the first embodiment;

FIGS. 3A and 3B are an enlarged cross-sectional view and a perspective view illustrating the structure of the semiconductor device of the first embodiment;

FIG. 4 is a cross-sectional view illustrating the structure of a semiconductor device of a comparative example of the first embodiment;

FIGS. 5A to 10B are cross-sectional views illustrating a method of manufacturing the semiconductor device of the first embodiment;

FIG. 11 is a plan view illustrating the structure of the semiconductor device of the first embodiment;

FIG. 12 is a cross-sectional view illustrating the structure of a semiconductor device of a second embodiment;

FIGS. 13 and 14 are cross-sectional views illustrating a method of manufacturing the semiconductor device of the second embodiment;

FIG. 15 is a cross-sectional view illustrating the structure of a semiconductor device of a third embodiment;

FIGS. 16A to 18B are cross-sectional views illustrating a method of manufacturing the semiconductor device of the third embodiment;

FIGS. 19A and 19B are a cross-sectional view illustrating a method of manufacturing a semiconductor device of a comparative example of the third embodiment;

FIG. 20 is a cross-sectional view illustrating the structure of a semiconductor device of a fourth embodiment; and

FIGS. 21A to 22B are cross-sectional views illustrating a method of manufacturing the semiconductor device of the fourth embodiment.

### DETAILED DESCRIPTION

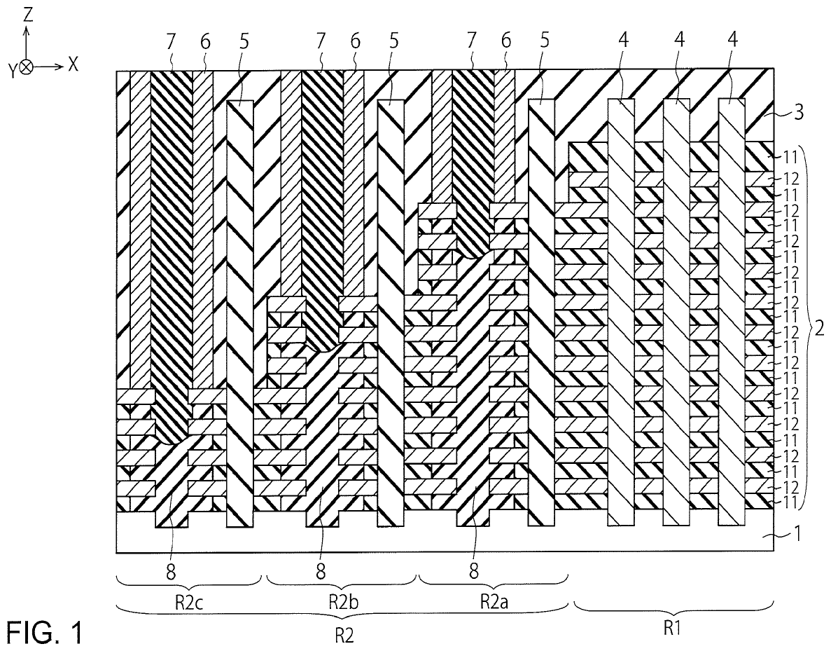

Embodiments will now be explained with reference to the accompanying drawings. Identical components in FIGS. 1 to 22B are denoted by the same reference sign, and duplicate description thereof is omitted.

In one embodiment, a semiconductor device includes a stacked film including a plurality of first insulators and a plurality of electrode layers that are alternately stacked in a first direction. The device includes a first plug provided on a first electrode layer among the plurality of electrode layers, and having a tube shape extending in the first direction. The device includes a second insulator provided in the first plug and the first electrode layer, and having a columnar shape extending in the first direction. Furthermore, a diameter of a side face of the first plug enclosing the second insulator is larger than a diameter of a side face of the first electrode layer enclosing the second insulator.

### First Embodiment

FIG. 1 is a cross-sectional view illustrating the structure of a semiconductor device of a first embodiment. The semiconductor device of the present embodiment includes, for example, a three-dimensional semiconductor memory.

The semiconductor device of the present embodiment includes a source layer 1, a stacked film 2, an inter layer dielectric 3, a plurality of columnar portions 4, a plurality of beam portions 5, a plurality of contact plugs 6, a plurality of insulators 7, and a plurality of insulators 8. The stacked film 2 includes a plurality of insulators 11 and a plurality of electrode layers 12. The insulators 11, the insulators 7, the insulators 8, the inter layer dielectric 3, and the beam portions 5 are examples of first, second, third, fourth, and fifth insulators, respectively. The contact plugs 6 are examples of a first plug.

In FIG. 1, an X direction, a Y direction, and a Z direction that are orthogonal to one another are illustrated to indicate the orientation of the semiconductor device of the present embodiment. In the specification, the +Z direction is treated as an up direction, and the −Z direction is treated as a down direction. The −Z direction may or may not be aligned with the direction of gravity. The Z direction is an example of a first direction.

The semiconductor device of the present embodiment may include one substrate on the lower or upper side of the source layer 1, the stacked film 2, and the inter layer dielectric 3 or may include two substrates on the lower and upper sides of the source layer 1, the stacked film 2, and the inter layer dielectric 3. In the present embodiment, a non-illustrated substrate is disposed on the upper side of the source layer 1, the stacked film 2, and the inter layer dielectric 3, and the surface of the substrate is parallel to the X direction and the Y direction and orthogonal to the Z direction.

The source layer 1 is provided below the stacked film 2 and functions as a source line. The source layer 1 is, for example, a stacked film including a semiconductor layer and a metal layer. The source layer 1 of the present embodiment extends in the X direction.

The stacked film 2 is provided between the source layer 1 and the inter layer dielectric 3. The stacked film 2 includes the plurality of insulators 11 and the plurality of electrode layers 12 alternately stacked in the Z direction. Each insulator 11 is, for example, a silicon oxide film (SiO₂ film). For example, each electrode layer 12 includes a titanium nitride film (TiN film) as a barrier metal layer and includes a tungsten (W) layer as an electrode material layer. Each electrode layer 12 functions as, for example, a word line or a selection line. The stacked film 2 includes a flat portion R1 having a flat shape and a step structure portion R2 having a step shape. The step structure portion R2 includes a plurality of portions R2a to R2c. Each of the portions R2a to R2c corresponds to a step and is also called a terrace portion.

The inter layer dielectric 3 is provided on the stacked film 2. The inter layer dielectric 3 is, for example, a SiO₂ film. The inter layer dielectric 3 of the present embodiment covers the upper and side faces of the flat portion R1 and the step structure portion R2.

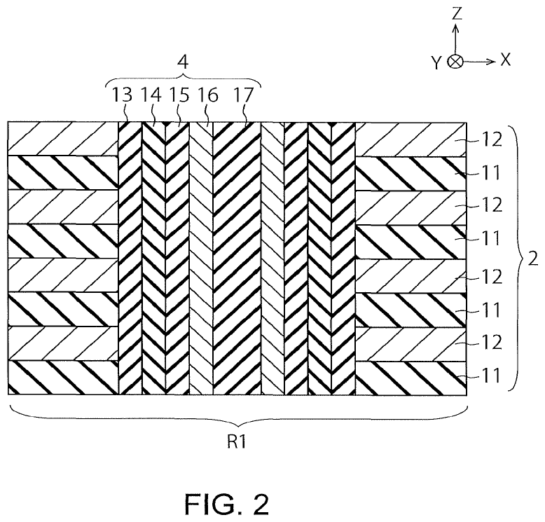

The above-described plurality of columnar portions 4 are provided in the flat portion R1 and penetrate through the stacked film 2 in the Z direction. The columnar portions 4 each have a columnar shape extending in the Z direction and form a plurality of cell transistors (memory cells) and a plurality of selection transistors (selection gate) together with the above-described plurality of electrode layers 12. The structure of each columnar portion 4 will be described later in more detail with reference to FIG. 2.

The above-described plurality of beam portions 5 are provided in the step structure portion R2 and penetrate through the stacked film 2 in the Z direction. Each beam portion 5 has a columnar shape extending in the Z direction and functions as a beam for preventing collapse of the stacked film 2 in a replacement process. Each beam portion 5 is formed of, for example, an insulator such as a SiO₂ film. In the present embodiment, the columnar portions 4 and the beam portions may have the same length in the Z direction or may have different lengths in the Z direction.

FIG. 1 exemplarily illustrates one beam portion 5 provided in the portion R2a, one beam portion 5 provided in the portion R2b, and one beam portion 5 provided in the portion R2c. The beam portion 5 in the portion R2a penetrates through all insulators 11 and electrode layers 12 in the portion R2a and reaches the source layer 1 like the columnar portions 4. Similarly, the beam portion 5 in the portion R2b penetrates through all insulators 11 and electrode layers 12 in the portion R2b, and the beam portion 5 in the portion R2c penetrates through all insulators 11 and electrode layers 12 in the portion R2c.

The above-described plurality of contact plugs 6 are provided on the step structure portion R2 in the inter layer dielectric 3. Each contact plug 6 has a tube shape extending in the Z direction. For example, the contact plug 6 includes a TiN film as a barrier metal layer and includes a W layer as a plug material layer. In the present embodiment, each beam portion 5 and the corresponding contact plug 6 are separated from each other.

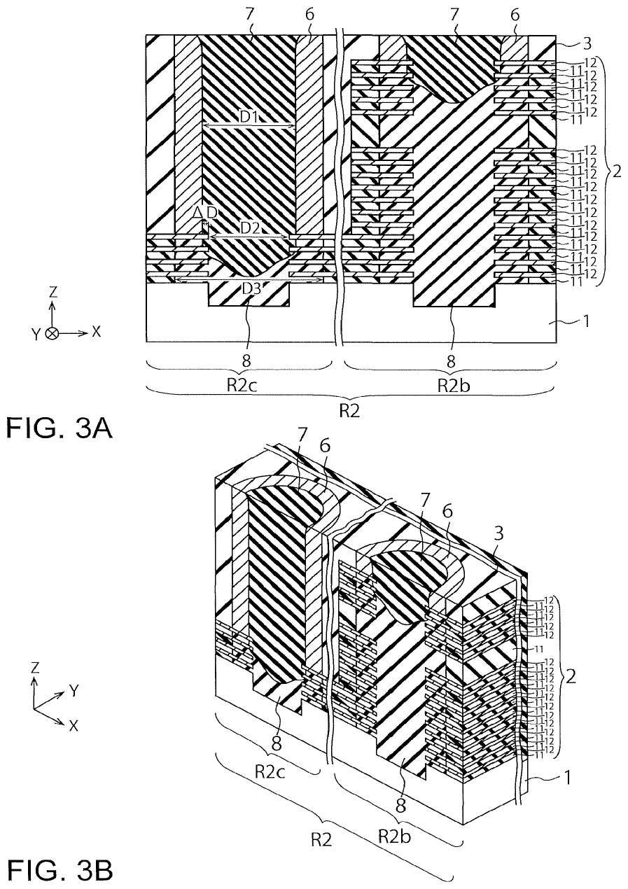

FIG. 1 exemplarily illustrates one contact plug 6 provided on the portion R2a, one contact plug 6 provided on the portion R2b, and one contact plug 6 provided on the portion R2c. The contact plug 6 on the portion R2a is disposed on a topmost electrode layer 12 among the plurality of electrode layers 12 in the portion R2a and electrically connected to the topmost electrode layer 12. The topmost electrode layer 12 is an example of a first electrode layer. Similarly, the contact plug 6 on the portion R2b is disposed on a topmost electrode layer 12 among the plurality of electrode layers 12 in the portion R2b, and the contact plug 6 on the portion R2c is disposed on a topmost electrode layer 12 among the plurality of electrode layers 12 in the portion R2c. Each contact plug 6 electrically connects the corresponding topmost electrode layer 12 and a non-illustrated transistor. The structure of each contact plug 6 will be described later in more detail with reference to FIGS. 3A and 3B.

The above-described plurality of insulators 7 are provided on the step structure portion R2 and in the step structure portion R2. Each insulator 7 has a columnar shape extending in the Z direction and is embedded in the corresponding contact plug 6. Each insulator 7 is, for example, a SiO₂ film.

FIG. 1 exemplarily illustrates one insulator 7 embedded in the contact plug 6 positioned on the portion R2a, one insulator 7 embedded in the contact plug 6 positioned on the portion R2b, and one insulator 7 embedded in the contact plug 6 positioned on the portion R2c. The insulator 7 on the portion R2a is also embedded in the topmost and next topmost electrode layers 12 among the plurality of electrode layers 12 in the portion R2a. This is the same for the insulator 7 on the portion R2b and the insulator 7 on the portion R2c.

The above-described plurality of insulators 8 are provided in the step structure portion R2. Each insulator 8 has a substantially columnar shape extending in the Z direction and is disposed below the corresponding insulator 7. Each insulator 8 is, for example, a low-pressure phospho-silicate glass (LP-PSG) film and is a SiO₂ film including phosphorus (P) as impurity. The insulators 8 of the present embodiment are formed of a kind of an insulating material (LP-PSG) that is different from a kind of the insulating material (SiO₂) that forms the insulators 7. With this configuration, the P atom concentration in the insulators 8 of the present embodiment is higher than the P atom concentration in the insulators 7. With this configuration, for example, it is possible to increase etching selectivity of the insulators 7 and the insulators 8.

FIG. 1 exemplarily illustrates an insulator 8 embedded in the portion R2a, an insulator 8 embedded in the portion R2b, and an insulator 8 embedded in the portion R2c. The insulator 8 in the portion R2a is embedded in the electrode layers 12 except for the topmost and next topmost electrode layers 12 among the plurality of electrode layers 12 in the portion R2a. This is the same for the insulator 8 in the portion R2b and the insulator 8 in the portion R2c.

FIG. 2 is an enlarged cross-sectional view illustrating the structure of the semiconductor device of the first embodiment. FIG. 2 exemplarily illustrates one of the above-described plurality of columnar portions 4.

Each columnar portion 4 of the present embodiment includes a block insulator 13, a charge storage layer 14, a tunnel insulator 15, a channel semiconductor layer 16, and a core insulator 17 sequentially provided in the flat portion R1 as illustrated in FIG. 2.

The block insulator 13, the charge storage layer 14, the tunnel insulator 15, and the channel semiconductor layer 16 each have a tube shape extending in the Z direction, and the core insulator 17 has a columnar shape extending in the Z direction. The block insulator 13 is, for example, a SiO₂ film. The charge storage layer 14 is, for example, an insulator such as a silicon nitride film (SiN film), or a semiconductor layer such as a polysilicon layer. The charge storage layer 14 can store signal charge for the corresponding memory cell. The tunnel insulator 15 is, for example, a SiO₂ film. The channel semiconductor layer 16 is, for example, a polysilicon layer. The channel semiconductor layer 16 is electrically connected to the source layer 1 (FIG. 1) and a bit line (not illustrated). The core insulator 17 is, for example, a SiO₂ film.

FIGS. 3A and 3B are an enlarged cross-sectional view and a perspective view illustrating the structure of the semiconductor device of the first embodiment.

The enlarged cross-sectional view in FIG. 3A and the perspective view in FIG. 3B illustrate the portions R2b and R2c of the step structure portion R2. The portions R2b and R2c illustrated in FIGS. 3A and 3B are different from the portions R2b and R2c illustrated in FIG. 1 in, for example, the number of stacked insulators 11 and the number of stacked electrode layers 12, but have substantially the same structures as the portions R2b and R2c illustrated in FIG. 1. The shapes of each contact plug 6, each insulator 11, and each electrode layer 12 of the present embodiment will be described below with the contact plug 6 on the portion R2c and the insulator 11 and the electrode layer 12 in the portion R2c as examples.

The contact plug 6 on the portion R2c has a tube shape extending in the Z direction. Specifically, the contact plug 6 has an inner peripheral side face enclosing the corresponding insulator 7, and an outer peripheral side face enclosed by the inter layer dielectric 3. The XY sectional shape of the contact plug 6 is, for example, a circle. The circle may be an exact circle or a circle in a shape distorted from an exact circle but is desirably a circle in a shape close to an exact circle. FIG. 3A illustrates a diameter D1 of the inner peripheral side face of the contact plug 6.

Each electrode layer 12 in the portion R2c is penetrated by the corresponding insulator 7 or 8. With this configuration, each electrode layer 12 has a side face enclosing the insulator 7 or 8. The XY sectional shape of the side face is, for example, a circle. The circle may be an exact circle or a circle in a shape distorted from an exact circle but is desirably a circle in a shape close to an exact circle. FIG. 3A illustrates a diameter D2 of the side face of each electrode layer 12. In the portion R2c illustrated in FIG. 3A, the side faces of the topmost and next topmost electrode layers 12 enclose the insulator 7, and the side faces of the other electrode layers 12 enclose the insulator 8 or the insulators 7 and 8. The side face of an electrode layer 12 and the side face of another electrode layer 12 may have diameters D2 of values different from each other.

Each insulator 11 in the portion R2c is penetrated by the corresponding insulator 7 or 8. With this configuration, each insulator 11 has a side face enclosing the insulator 7 or 8. The XY sectional shape of the side face is, for example, a circle. The circle may be an exact circle or a circle in a shape distorted from an exact circle but is desirably a circle in a shape close to an exact circle. FIG. 3A illustrates a diameter D3 of the side face of each insulator 11. In the portion R2c illustrated in FIG. 3A, the insulators 11 enclose the insulator 8 or the insulators 7 and 8. The side face of an insulators 11 and the side face of another insulators 11 may have diameters D3 of values different from each other.

The diameters D1 to D3 will be described below in more detail.

In the present embodiment, holes for the beam portions 5 and holes (contact holes) for the contact plugs 6 are simultaneously formed in the stacked film 2 and the inter layer dielectric 3. For this reason, the holes for the beam portions 5 and the holes for the contact plugs 6 are formed to have the same depth. The insulators 7 and 8 are formed in the contact holes formed in this manner. In the present embodiment, the holes for the beam portions 5 and the holes for the contact plugs 6 are formed after holes (memory holes) for the columnar portions 4 are formed in the stacked film 2 and the inter layer dielectric 3 and the columnar portions 4 are formed in the holes for the columnar portions 4.

In the present embodiment, when the contact holes are formed in the stacked film 2 and the inter layer dielectric 3, the side faces of the insulators 11 are recessed with respect to the side faces of sacrifice layers for the electrode layers 12. As a result, the diameter D3 of the side faces of the insulators 11 is larger than the diameter D2 of the side faces of the electrode layers 12 (D3>D2). In addition, the side face of the inter layer dielectric 3 is recessed with respect to the side faces of the sacrifice layers for the electrode layers 12. As a result, the upper face of the topmost sacrifice layer is exposed in the contact holes, and the contact plugs 6 are formed on the topmost electrode layer 12.

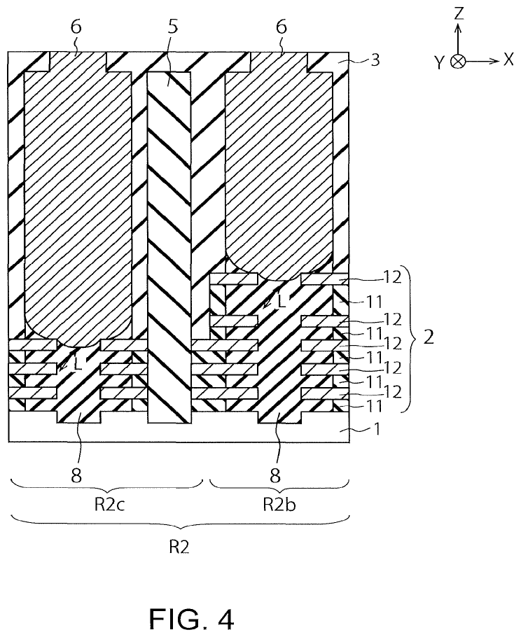

FIG. 3A illustrates a difference ΔD between the half value of the diameter D1 of the inner peripheral side face of each contact plug 6 and the half value of the diameter D2 of the side faces of the corresponding electrode layers 12 (ΔD=(D1−D2)/2). Each contact plug 6 of the present embodiment is formed such that the diameter D1 of the inner peripheral side face of the contact plug 6 is larger than the diameter D2 of the side faces of the corresponding electrode layers 12 (D1>D2). As a result, the side face of the topmost electrode layer 12 protrudes on the inner peripheral side of the inner peripheral side face of the contact plug 6. With this configuration, the contact plug 6 as a whole can be easily placed on the topmost electrode layer 12. Such protrusion of the contact plug 6 will be described later in more detail with reference to FIG. 4.

In a case in which the diameter D2 of the side faces of the electrode layers 12 is different among the electrode layers 12, each contact plug 6 of the present embodiment is formed such that the diameter D1 of inner peripheral side face of the contact plug 6 is larger than the diameter D2 of the side face of the topmost electrode layer 12. With this configuration, the side face of the topmost electrode layer 12 protrudes on the inner peripheral side of the inner peripheral side face of the contact plug 6.

FIG. 4 is a cross-sectional view illustrating the structure of a semiconductor device of a comparative example of the first embodiment.

Similarly to FIG. 3A, FIG. 4 illustrates the portions R2b and R2c of the step structure portion R2. However, each contact plug 6 of the comparative example has a columnar shape extending in the Z direction although each contact plug 6 of the first embodiment has a tube shape extending in the Z direction. In other words, each contact plug 6 of the comparative example has a solid shape, whereas each contact plug 6 of the first embodiment has a hollow shape.

FIG. 4 illustrates a distance L between the contact plug 6 and the next topmost electrode layer 12 in each of the portions R2b and R2c. It is expected that breakdown voltage between the contact plug 6 and a non-selection word line decreases when the distance L is short. Each contact plug 6 of the comparative example has a solid shape, and the lower end of the contact plug 6 is positioned near the center of an opening portion (contact hole) in the topmost electrode layer 12. With this configuration, the distance L of the comparative example is substantially equal to the distance between the lower end of the contact plug 6 and the side face of the next topmost electrode layer 12. As a result, it is thought that the distance L of the comparative example is likely to be short.

However, each contact plug 6 of the present embodiment has a hollow shape, and the lower end of the contact plug 6 is positioned on the topmost electrode layer 12. With this configuration, according to the present embodiment, the contact plugs 6 is positioned far away from the next topmost electrode layer 12, and breakdown voltage between the contact plug 6 and a non-selection word line can be improved. Moreover, according to the present embodiment, since the side face of the topmost electrode layer 12 protrudes on the inner peripheral side of the inner peripheral side face of the contact plug 6, the contact plug 6 is positioned farther away from the next topmost electrode layer 12. This leads to further improvement of the above-described breakdown voltage.

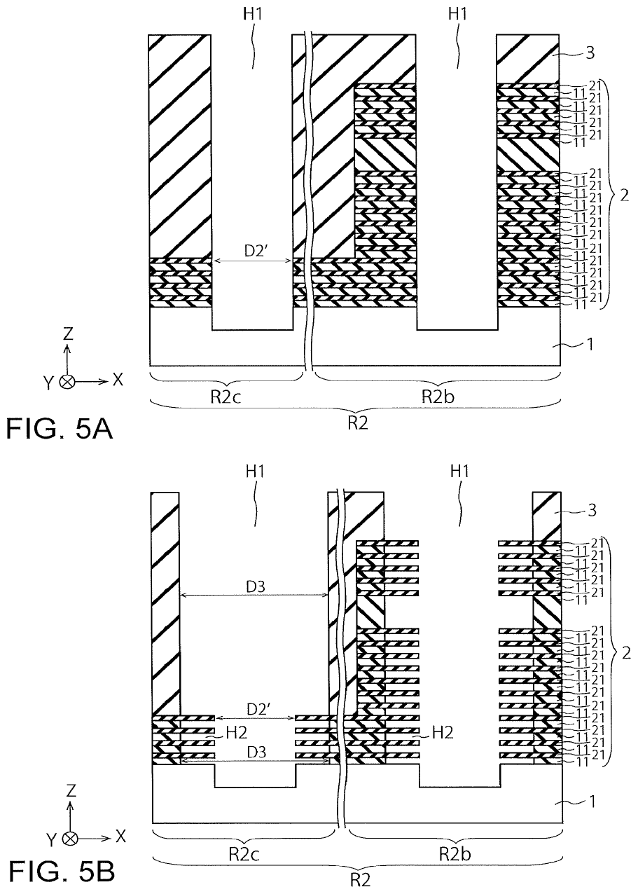

FIGS. 5A to 10B are cross-sectional views illustrating the method of manufacturing the semiconductor device of the first embodiment.

First, the source layer 1 is formed, and the stacked film 2 is formed on the source layer 1 (FIG. 5A). The stacked film 2 is formed by alternately stacking a plurality of insulators 11 and a plurality of sacrifice layers 21 on the source layer 1. Each sacrifice layer 21 is, for example, a SiN film. Each sacrifice layer 21 is an example of a first film. Similarly to the stacked film 2 illustrated in FIG. 1, the stacked film 2 illustrated in FIG. 5A is formed to include the flat portion R1 and the step structure portion R2. FIG. 5A illustrates the portions R2b and R2c in the step structure portion R2 but omits illustration of the flat portion R1 and the portion R2a.

Subsequently, the inter layer dielectric 3 is formed on the stacked film 2, and a plurality of contact holes H1 are formed in the inter layer dielectric 3 and the stacked film 2 by lithography and reactive ion etching (RIE) (FIG. 5A). Each contact hole H1 of the present embodiment is formed to have a diameter D2′ and reach the source layer 1. The diameter D2′ is set to be smaller than the above-described diameter D2 with taking into consideration formation of a block insulator 23 to be described later. FIG. 5A exemplarily illustrates one contact hole H1 formed in the portion R2b and one contact hole H1 formed in the portion R2c. Simultaneously with formation of these contact holes H1, the holes for the beam portions 5 (not illustrated) are formed in the stacked film 2 and the inter layer dielectric 3 by the above-described lithography and RIE. Each contact hole H1 is an example of a first concave portion.

Subsequently, the side faces of the insulators 11 and the inter layer dielectric 3 are recessed with respect to the side faces of the sacrifice layers 21 in each contact hole H1 by wet etching using drug solution (FIG. 58). As a result, a plurality of concave portions H2 are formed in regions from which the insulators 11 are removed. The inter layer dielectric 3, the insulators 11, and the sacrifice layers 21 of the present embodiment are, for example, a SiO₂ film, SiO₂ films, and SiN films, respectively. Accordingly, the insulators 11 and the inter layer dielectric 3 can be selectively etched in this manner. In FIG. 5B, the side faces of the insulators 11 and the inter layer dielectric 3 are processed to have the diameter D3. The above-described wet etching is performed such that the side faces of the contact holes H1 do not reach the side faces of the holes for the beam portions 5.

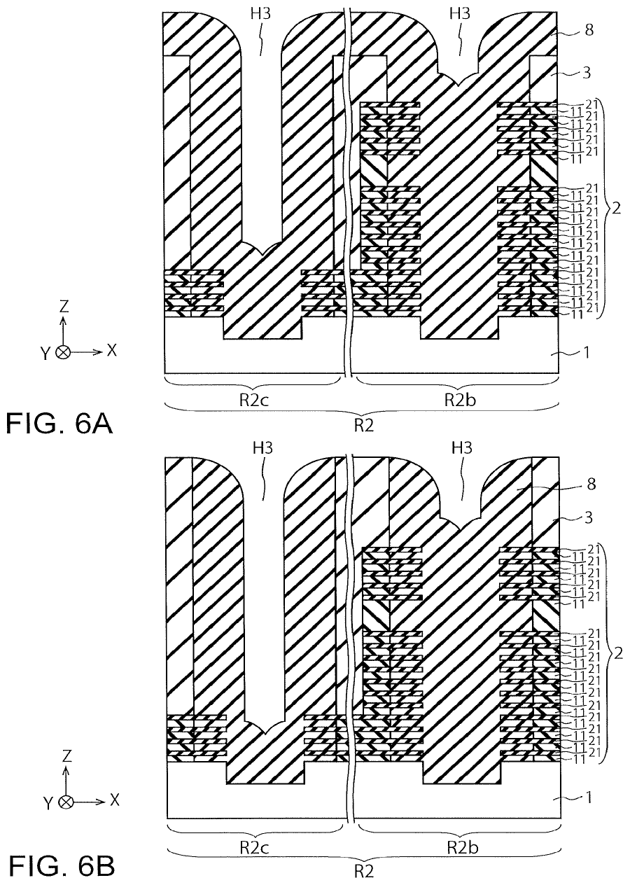

Subsequently, the insulators 8 are formed on the inter layer dielectric 3 and the stacked film 2 (FIG. 6A). As a result, the insulators 8 are formed on the bottom and side faces of the contact holes H1 and the upper face of the inter layer dielectric 3. FIG. 6A illustrates concave portions H3 remaining in the contact holes H1. Each insulator 8 is, for example, an LP-PSG film.

Subsequently, the insulators 8 are etched by RIE (FIG. 6B)). As a result, the concave portions H3 in the insulators 8 become deep and the insulators 8 are removed from the upper face of the inter layer dielectric 3.

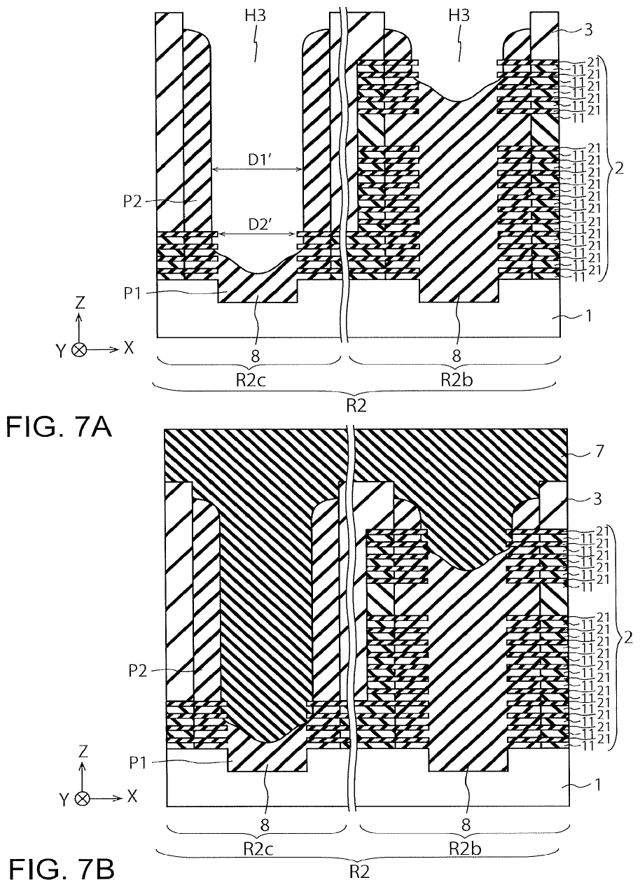

Subsequently, the insulators 8 are selectively etched by wet etching using drug solution (FIG. 7A). As a result, the insulator 8 in each contact hole H1 is divided into, for example, a lower portion P1 in the stacked film 2 and an upper portion P2 on the stacked film 2. The lower portion P1 is an example of a first portion, and the upper portion P2 is an example of a second portion. In each contact hole H1 illustrated in FIG. 7A, the side faces of the topmost and next topmost sacrifice layers 21 are exposed from the insulator 8. In FIG. 7A, the inner peripheral side face of the upper portion P2 is processed to have a diameter D1′. The diameter D1′ is set to be smaller than the above-described diameter D1 with taking into consideration formation of the block insulator 23 to be described later.

Subsequently, the insulators 7 are formed on the insulators 8, the inter layer dielectric 3, and the stacked film 2 (FIG. 7B). As a result, the insulators 7 are formed on the bottom and side faces of the concave portions H3 and the upper face of the inter layer dielectric 3. Each insulator 7 is, for example, a SiO₂ film.

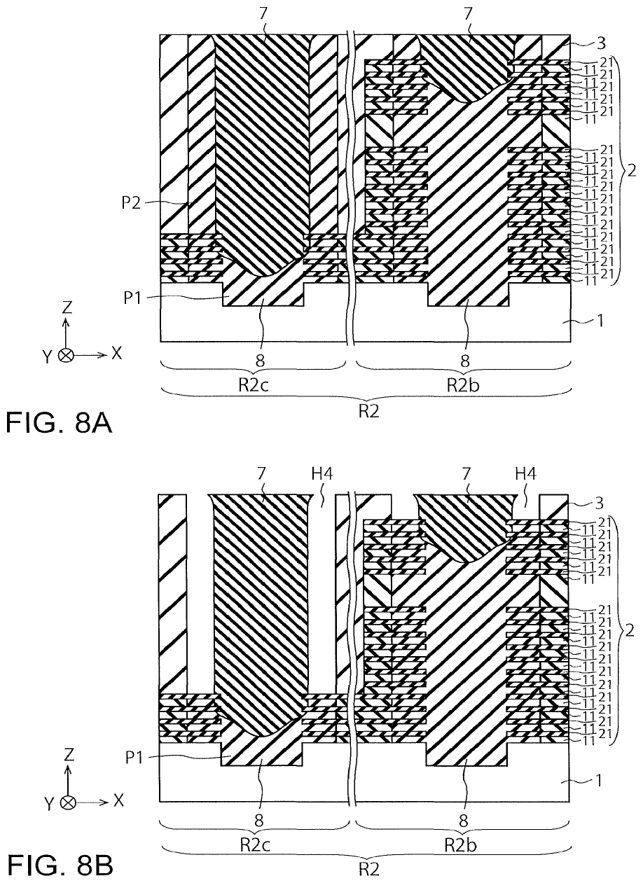

Subsequently, the upper faces of the insulators 7 are flattened by chemical mechanical polishing (CMP) (FIG. 8A). As a result, the upper faces of the insulators 8 and the inter layer dielectric 3 are exposed from the insulators 7. In each contact hole H1, the insulator 7 is formed in the upper portion P2 on the lower portion P1.

Subsequently, the insulators 8 are selectively etched by wet etching using drug solution (FIG. 8B). As a result, the upper portion P2 is removed from each contact hole H1, and a concave portion H4 is formed in the contact hole H1. Each concave portion H4 has a tube shape extending in the Z direction and is formed between the insulator 7 and the inter layer dielectric 3. Each concave portion H4 is an example of a second concave portion.

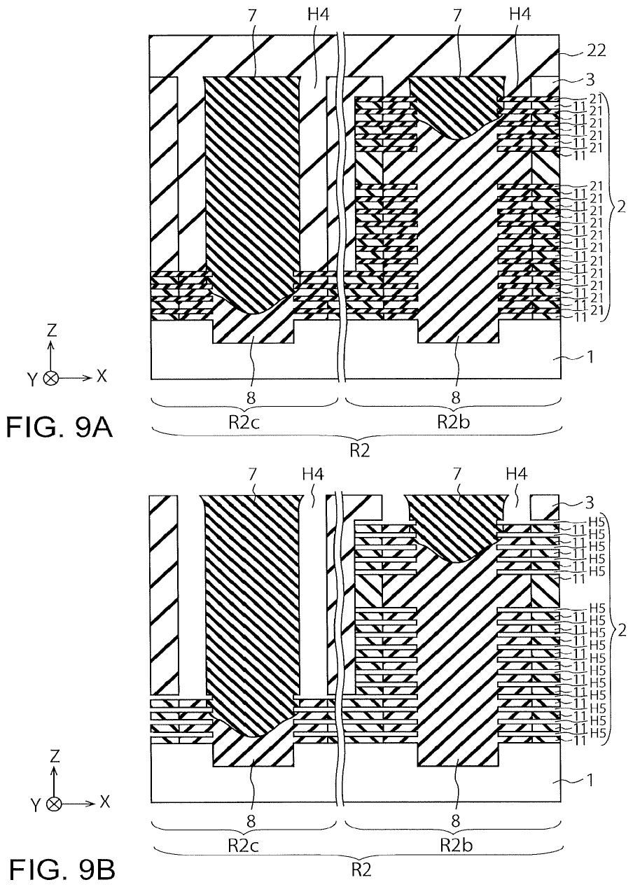

Subsequently, a sacrifice layer 22 is formed on the insulators 7, the inter layer dielectric 3, and the stacked film 2 (FIG. 9A). As a result, the sacrifice layer 22 is formed inside the concave portions H4 and on the upper faces of the insulators 7 and the inter layer dielectric 3. The sacrifice layer 22 is, for example, a SiN film.

Subsequently, the sacrifice layers 21 and 22 are selectively etched by wet etching using drug solution (FIG. 9B). As a result, a plurality of concave portions H5 are formed in regions from which the sacrifice layers 21 are removed, and a plurality of concave portions H4 are formed again in regions from which the sacrifice layer 22 is removed. Each concave portion H5 is an example of a third concave portion.

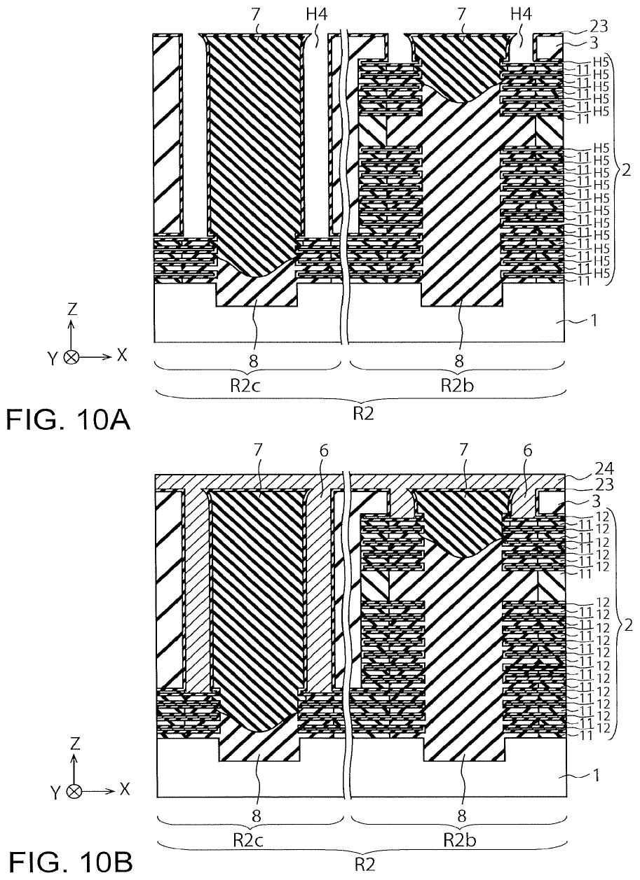

Subsequently, the block insulator 23 is formed on the inner faces of the concave portions H4 and H5 (FIG. 10A). The block insulator 23 is, for example, an aluminum oxide film. The block insulator 23 functions as a block insulator of each memory cell together with the block insulator 13 illustrated in FIG. 2.

Subsequently, a metal layer 24 is formed on the inner faces of the concave portions H4 and H5 (FIG. 10B). As a result, the metal layer 24 is embedded in the concave portions H4 and H5 via the block insulator 23. The metal layer 24 in each concave portion H4 becomes a contact plug 6, and the metal layer 24 in each concave portion H5 becomes an electrode layer 12. In this manner, the contact plugs 6 and the electrode layers 12 of the present embodiment are formed of the same metal layer 24. Each contact plug 6 is formed on the corresponding topmost electrode layer 12 and electrically connected to the topmost electrode layer 12. Each contact plug 6 and each electrode layer 12 are formed to have the diameters D1 and D2 illustrated in FIGS. 3A and 3B, respectively.

The metal layer 24 includes, for example, one or more kinds of metal elements among tungsten (W), aluminum (Al), copper (Cu), titanium (Ti), tantalum (Ta), and ruthenium (Ru). The metal layer 24 of the present embodiment includes a TiN film as a barrier metal layer and includes W layers as a plug material layer and an electrode material layer. However, the barrier metal layer in the metal layer 24 may be other than a TiN film, and the plug material layer and the electrode material layer in the metal layer 24 may be other than W layers. For example, the barrier metal layer may be a single-metal layer such as a Ti layer or a Ta layer or may be a metal compound layer such as a TiN layer or a TaN layer.

Thereafter, the block insulator 23 and the metal layer 24 outside the concave portions H4 and H5 are removed by CMP. In this manner, the semiconductor device illustrated in FIGS. 3A and 3B is manufactured.

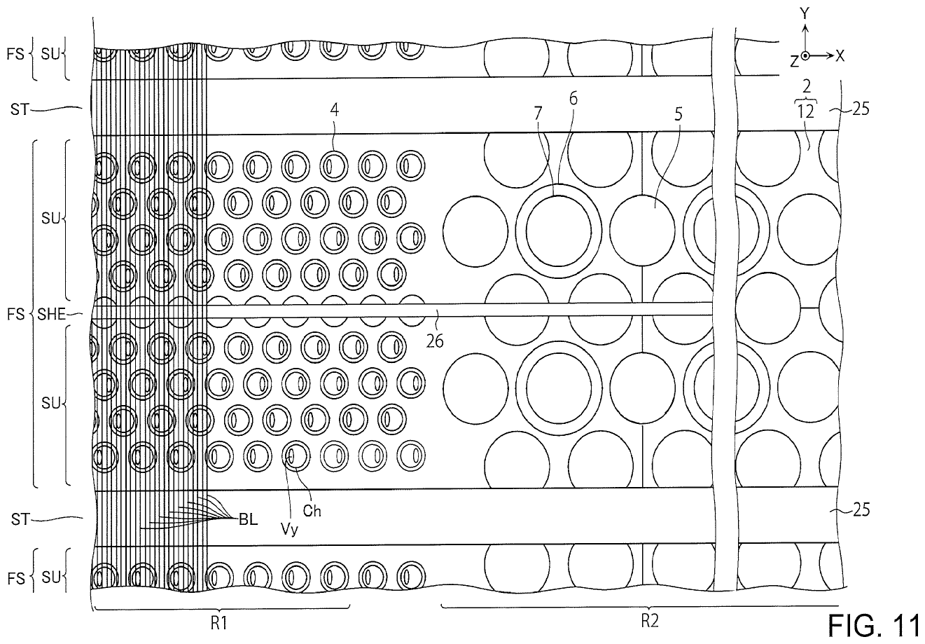

FIG. 11 is a plan view illustrating the structure of the semiconductor device of the first embodiment.

Similarly to FIG. 1, FIG. 11 illustrates the columnar portions 4 in the flat portion R1, and the beam portions 5, the contact plugs 6, and the insulators 7 in the step structure portion R2. However, the step structure portion R2 illustrated in FIG. 11 is positioned in the positive X direction with respect to the flat portion R1 although the step structure portion R2 illustrated in FIG. 1 is positioned in the negative X direction with respect to the flat portion R1. Moreover, the step structure portion R2 illustrated in FIG. 11 has one step although the step structure portion R2 illustrated in FIG. 1 has three steps.

FIG. 11 also illustrates two slits ST extending in the X direction and one trench SHE extending in the X direction between the slits ST. Each slit ST penetrates through the stacked film 2 and is filled with an insulator 25. The trench SHE penetrates through one or more electrode layers 12 that function as drain-side selection lines among the plurality of electrode layers 12 included in the stacked film 2, and is filled with an insulator 26.

In the flat portion R1 in FIG. 11, a region between the two slits ST corresponds to one finger structure FS in one block of a three-dimensional semiconductor memory. The finger structure FS includes two string units SU arranged in the Y direction. The trench SHE is provided between the string units SU. FIG. 11 also illustrates contact plugs Ch and Vy sequentially provided on each columnar portion 4, and a plurality of bit lines BL extending in the Y direction.

As described above, each contact plug 6 of the present embodiment has a tube shape extending in the Z direction, is formed on the electrode layers 12 included in the step structure portion R2, and encloses the corresponding insulator 7 together with the electrode layers 12. Moreover, the diameter D1 of the inner peripheral side face of each contact plug 6 is set to be larger than the diameter D2 of the side face of each electrode layer 12. With this configuration, according to the present embodiment, each contact plug 6 can be excellently formed on the electrode layers 12 such that, for example, breakdown voltage between the contact plug 6 and a non-selection word line can be improved.

The beam portions 5 of the present embodiment are formed inside the holes for the beam portions 5 in any of the processes in FIG. 5B to FIG. 9A. The beam portions 5 function as beams for preventing collapse of the stacked film 2 in the replacement process in FIG. 9B to FIG. 10B. The sacrifice layers 21 are replaced with the electrode layers 12 in the replacement process.

### Second Embodiment

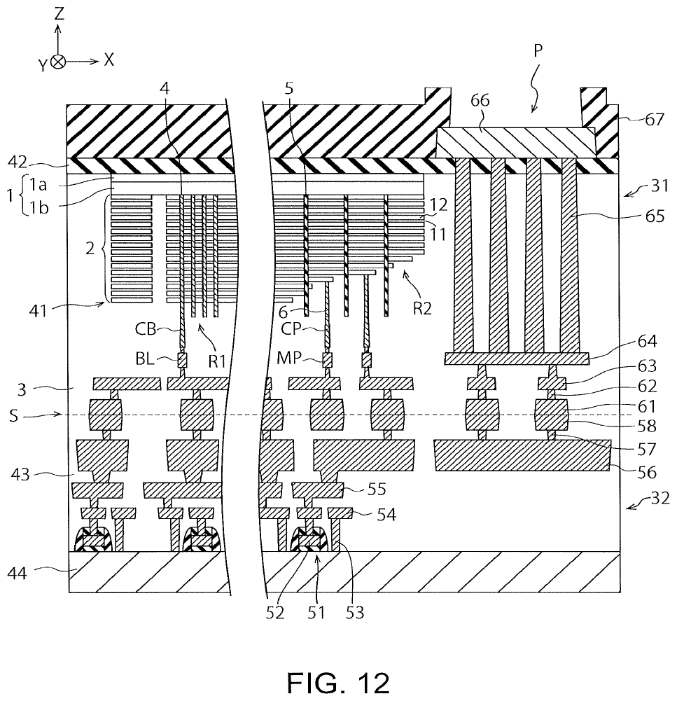

FIG. 12 is a cross-sectional view illustrating the structure of a semiconductor device of a second embodiment. The semiconductor device of the present embodiment is an example of the semiconductor device of the first embodiment. The semiconductor device of the present embodiment is a three-dimensional semiconductor memory in which an array chip 31 and a circuit chip 32 are bonded to each other.

The array chip 31 includes a memory cell array 41, an insulator 42 on the memory cell array 41, and the inter layer dielectric 3 below the memory cell array 41, the memory cell array 41 including the source layer 1, the stacked film 2, the columnar portions 4, the beam portions 5, and the contact plugs 6. The orientation of the semiconductor device illustrated in FIG. 12 is opposite the orientation of the semiconductor device illustrated in FIG. 1. FIG. 12 also illustrates the flat portion R1 and the step structure portion R2 in the stacked film 2 but omits illustration of the insulators 7 and the insulators 8. For sake of simplicity of illustration, each contact plug 6 is illustrated in a solid shape, not in a hollow shape.

The circuit chip 32 is positioned below the array chip 31. Reference sign S denotes a bonding face between the array chip 31 and the circuit chip 32. The circuit chip 32 includes an inter layer dielectric 43 and a substrate 44 below the inter layer dielectric 43. The substrate 44 is, for example, a semiconductor substrate such as a silicon substrate. In FIG. 12, the surface of the substrate 44 is parallel to the X and Y directions and orthogonal to the Z direction.

The array chip 31 includes, as a plurality of electrode layers in the memory cell array 41, the source layer 1 that functions as a source line and the plurality of electrode layers 12 that each function as a word line or a selection line. The electrode layers 12 are alternately stacked with the plurality of insulators 11. Each columnar portion 4 is electrically connected to the corresponding bit line BL through a contact plug CB and also electrically connected to the source layer 1. The source layer 1 includes a metal layer 1a and a semiconductor layer 1b. Each contact plug 6 is electrically connected to an interconnect MP through a contact plug CP.

The circuit chip 32 includes a plurality of transistors 51. Each transistor 51 includes a gate electrode 52 provided on the substrate 44 via a gate insulator, and a source diffusion layer and a drain diffusion layer (not illustrated) provided in the substrate 44. The circuit chip 32 also includes a plurality of contact plugs 53 each provided on the gate electrode 52, source diffusion layer, or drain diffusion layer of the corresponding transistor 51, an interconnect layer 54 provided on the contact plugs 53 and including a plurality of interconnects, and an interconnect layer 55 provided on the interconnect layer 54 and including a plurality of interconnects.

The circuit chip 32 also includes an interconnect layer 56 provided on the interconnect layer 55 and including a plurality of interconnects, a plurality of via plugs 57 provided on the interconnect layer 56, and a plurality of metal pads 58 provided on the via plugs 57. Each metal pad 58 is, for example, a metal layer including a Cu layer. The circuit chip 32 functions as a logic circuit (CMOS circuit) that controls operation of the array chip 31. The logic circuit is constituted by the transistors 51 and the like and electrically connected to the metal pads 58.

The array chip 31 includes a plurality of metal pads 61 provided on the metal pads 58, and a plurality of via plugs 62 provided on the metal pads 61. The array chip 31 also includes an interconnect layer 63 provided on the via plugs 62 and including a plurality of interconnects, and an interconnect layer 64 provided on the interconnect layer 63 and including a plurality of interconnects. The metal pads 61 is, for example, a metal layer including a Cu layer. The above-described bit lines BL and interconnects MP are included in the interconnect layer 64. The above-described logic circuit is electrically connected to the memory cell array 41 through the metal pads 58 and 61 and the like and controls operation of the memory cell array 41 through the metal pads 58 and 61 and the like. The logic circuit includes, for example, transistors 51 electrically connected to the bit lines BL through the metal pads 58 and 61 and the like, and transistors 51 electrically connected to the interconnects MP through the metal pads 58 and 61 and the like.

The array chip 31 also includes a plurality of via plugs 65 provided on the interconnect layer 64, a metal pad 66 provided on the via plugs 65 and the insulator 42, and a passivation film 67 provided on the metal pad 66 and the insulator 42. The metal pad 66 is, for example, a metal layer including a Cu layer and functions as an external connection pad (bonding pad) of the semiconductor device in FIG. 12. The passivation film 67 is, for example, an insulator such as a silicon oxide film and has an opening portion P through which the upper face of the metal pad 66 is exposed. The metal pad 66 is connectable to a mounting substrate or any other device through the opening portion P by using a bonding wire, a soldering ball, a metal bump, or the like.

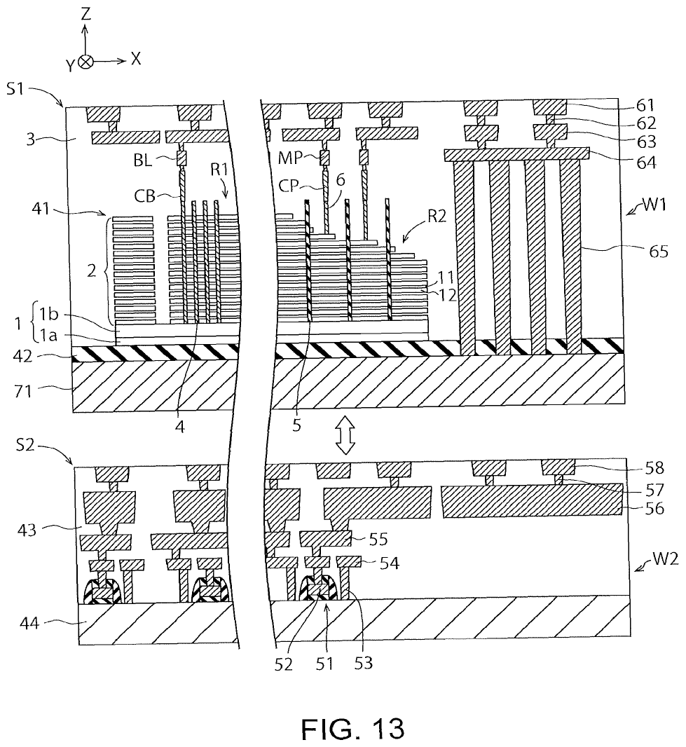

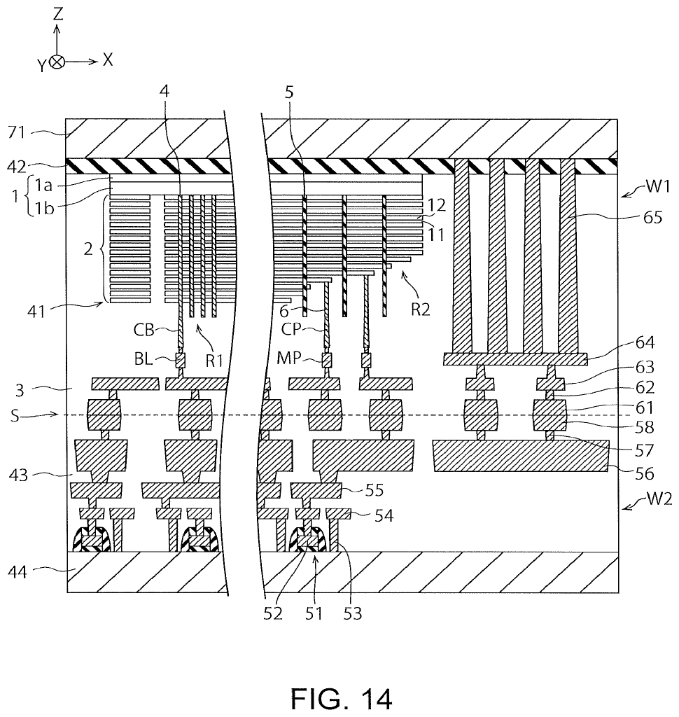

FIGS. 13 and 14 are cross-sectional views illustrating a method of manufacturing the semiconductor device of the second embodiment.

FIG. 13 illustrates an array wafer W1 including a plurality of array chips 31, and a circuit wafer W2 including a plurality of circuit chips 32. The orientation of the array wafer W1 illustrated in FIG. 13 is opposite the orientation of the array chip 31 illustrated in FIG. 12. In the present embodiment, the semiconductor device is manufactured by bonding the array wafer W1 and the circuit wafer W2 to each other. FIG. 13 illustrates the array wafer W1 before the orientation thereof is inverted for bonding, and FIG. 12 illustrates the array chip 31 after the orientation thereof is inverted for bonding and the array chip 31 is bonded and diced.

In FIG. 13, reference sign 51 denotes the upper face of the array wafer W1, and reference sign S2 denotes the upper face of the circuit wafer W2. The array wafer W1 includes a substrate 71 provided below the insulator 42. The substrate 71 is, for example, a semiconductor substrate such as a silicon substrate.

In the present embodiment, first, the memory cell array 41, the insulator 42, the source layer 1, the stacked film 2, the inter layer dielectric 3, the columnar portions 4, the beam portions 5, the contact plugs 6, the metal pads 61, and the like are formed on the substrate 71 of the array wafer W1, and the inter layer dielectric 43, the transistors 51, the metal pads 58, and the like are formed on the substrate 44 of the circuit wafer W2, as illustrated in FIG. 13. Subsequently, the array wafer W1 and the circuit wafer W2 are bonded to each other by mechanical pressure as illustrated in FIG. 14. Through this process, the inter layer dielectric 3 and the inter layer dielectric 43 are bonded to each other. Subsequently, the array wafer W1 and the circuit wafer W2 are annealed. Through this process, the metal pads 58 and the metal pads 61 are joined to each other.

Thereafter, the substrate 44 is thinned by CMP and the substrate 71 is removed by CMP, and then, the array wafer W1 and the circuit wafer W2 are disconnected into a plurality of chips. In this manner, the semiconductor device illustrated in FIG. 12 is manufactured. The metal pad 66 and the passivation film 67 are formed on the insulator 42, for example, after the thinning of the substrate 44 and the removal of the substrate 71.

Although FIG. 12 illustrates a boundary face between the inter layer dielectric 3 and the inter layer dielectric 43 and a boundary face between the metal pads 58 and the metal pads 61, these boundary faces typically cannot be observed after the above-described annealing. However, the positions of the boundary faces can be estimated by detecting, for example, tilt of the side faces of the metal pads 58 and the side faces of the metal pads 61, and positional shift between the side faces of the metal pads 58 and the metal pads 61.

According to the present embodiment, the structure described in the first embodiment can be applied to a semiconductor device in which the array chip 31 and the circuit chip 32 are bonded to each other. Although the array chip 31 and the circuit chip 32 are bonded to each other in the present embodiment, the array chips 31 may be bonded to each other instead.

### Third Embodiment

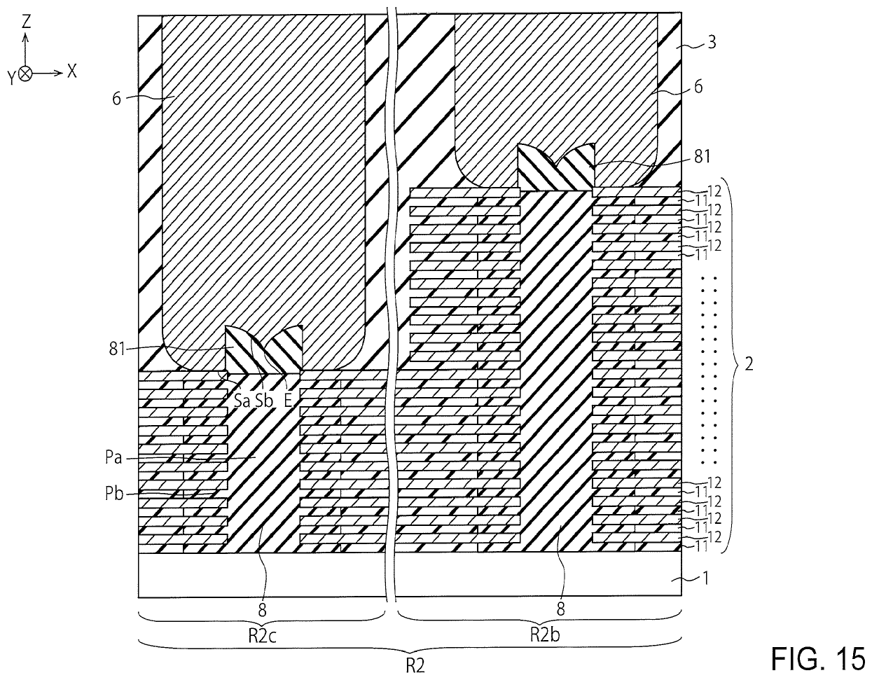

FIG. 15 is a cross-sectional view illustrating the structure of a semiconductor device of a third embodiment.

The semiconductor device of the present embodiment (FIG. 15) has the same structure as the semiconductor device of the first embodiment (for example, FIG. 1). However, each contact plug 6 of the present embodiment has a non-tube shape extending in the Z direction although each contact plug 6 of the first embodiment has a tube shape extending in the Z direction. Accordingly, each contact plug 6 of the present embodiment encloses no insulator 7 although each contact plug 6 of the first embodiment encloses the corresponding insulator 7. The semiconductor device of the present embodiment includes no insulators 7.

The semiconductor device of the present embodiment includes a plurality of insulators 81. Each insulator 81 is provided in the corresponding contact plug 6 near the bottom face of the contact plug 6. Each insulator 81 is formed, for example, by reforming portion of the insulators 8. The insulators 8 are reformed such that, for example, the etching rate of the insulators 81 is lower than the etching rate of the insulators 8. Each insulator 81 is, for example, a SiO₂ film including impurity atoms such as boron (B) atoms, nitrogen (N) atoms, or carbon (C) atoms. In this case, the concentration of the impurity atoms in the insulators 81 is higher than the concentration of the impurity atoms in the insulators 8. The insulators 81 may include P atoms as the impurity atoms like the insulators 8.

FIG. 15 also illustrates lower faces Sa and Sb of the contact plug 6 positioned on the portion R2c of the step structure portion R2. The lower face Sa is positioned on the topmost electrode layer 12 in the portion R2c. The lower face Sb is positioned higher than the lower face Sa and positioned on the corresponding insulator 81. FIG. 15 also illustrates a lower end E of the lower face Sb.

The lower face Sb has a shape similar to the side face of a circular cone having the lower end E as an apex. However, the shape of the lower face Sb is concave toward the inside of the circular cone with respect to the side face of the circular cone. Accordingly, a sectional shape of the lower face Sb in the cross-sectional view of FIG. 15 is not a shape with two sides of a triangle but a shape that is concave toward the inside of a triangle with respect to two sides of the triangle. In other words, tilt at a point on the lower face Sb is larger as the distance between the point and the lower end E is shorter. This is the same for the other contact plugs 6, for example, the contact plug 6 positioned on the portion R2b of the step structure portion R2. The reason for formation of the contact plugs 6 in such a shape will be described later. Each contact plug 6 of the present embodiment may have a lower face in a shape different from those of the lower faces Sa and Sb.

FIG. 15 also illustrates a portion Pa and a plurality of portions Pb of the insulator 8 positioned in the portion R2c of the step structure portion R2. The portion Pa is provided below the corresponding insulator 81 and has a columnar shape extending in the Z direction. The portion Pa penetrates through the stacked film 2 in the portion R2c. Each portion Pb has a shape annularly enclosing the portion Pa and is sandwiched between two electrode layers 12 adjacent to each other in the Z direction. The outer periphery of each portion Pb faces the inner peripheries of the insulators 11. This is the same for the other insulators 8, for example, the insulator 8 positioned in the portion R2b of the step structure portion R2. Such portions Pa and Pb are also provided at each insulator 8 of the first embodiment (refer to FIG. 1 and the like).

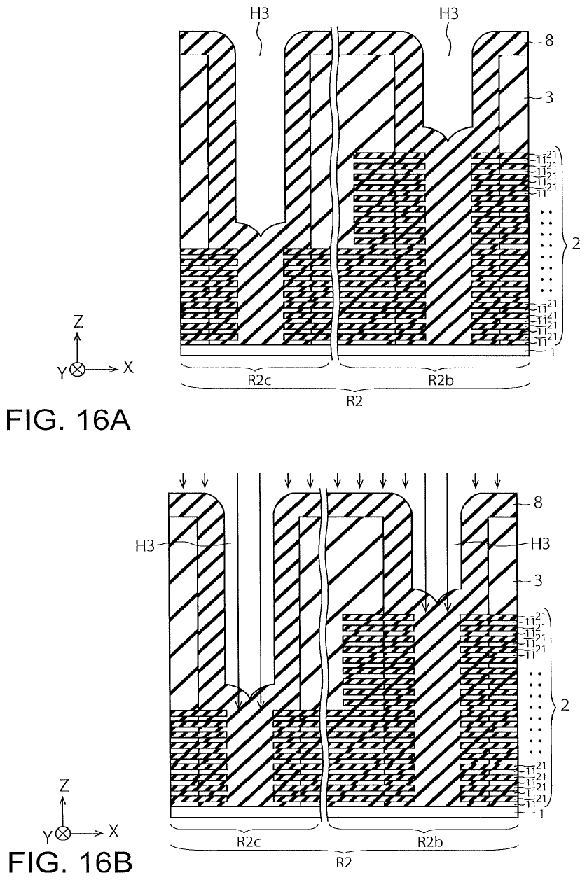

FIGS. 16A to 18B are cross-sectional views illustrating a method of manufacturing the semiconductor device of the third embodiment.

Similarly to FIG. 6A, FIG. 16A illustrates a process in which the insulators 8 are formed. In FIG. 16A, the upper face of the insulator 8 below each concave portion H3 has the same shape as the lower face Sb of each contact plug 6 illustrated in FIG. 15.

Subsequently, in the present embodiment, impurity atoms are implanted in the insulators 8 (FIG. 16B). This impurity atoms are, for example, B atoms, N atoms, or C atoms. In the present embodiment, the impurity atoms are implanted under a high directionality condition.

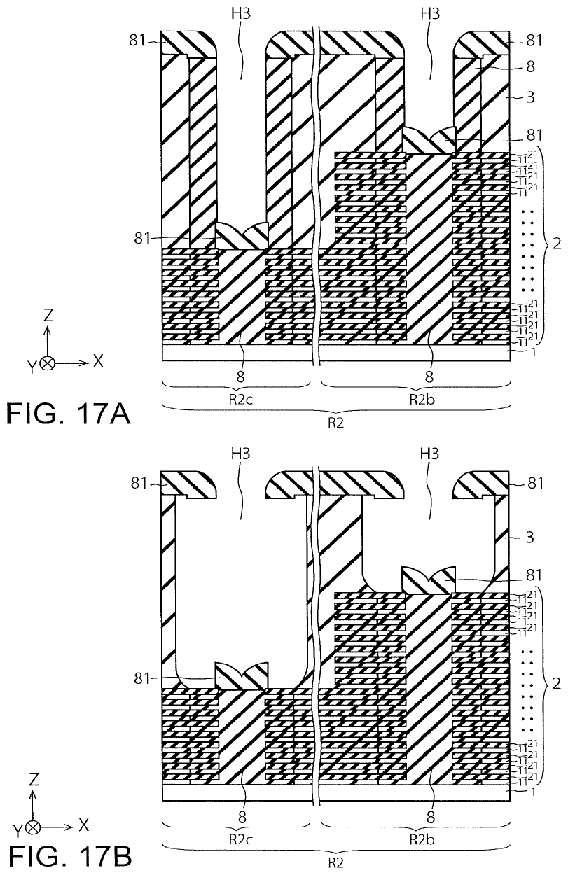

After the impurity atoms are implanted in the insulators 8 in a process illustrated in FIG. 16B, some of the insulators 8 are reformed into the insulators 81 (FIG. 17A). In the insulators 8, portions sufficiently hit by the impurity atoms are reformed. The impurity atoms are likely to hit portions near the upper faces of the insulators 8. For this reason, the insulators 8 below the concave portions H3 and the insulators 8 above the inter layer dielectric 3 are reformed into the insulators 81 in FIG. 17A. In the present embodiment, the etching rate of the insulators 81 is lower than the etching rate of the insulators 8. In FIG. 17A, the upper face of the insulator 81 below each concave portion H3 has the same shape as the lower face Sb of each contact plug 6 illustrated in FIG. 15.

Subsequently, the insulators 8 are removed from the side face of the inter layer dielectric 3 by wet etching (FIG. 17B). In this process, since the etching rate of the insulators 81 is lower than the etching rate of the insulators 8, the insulators 81 remain whereas the insulators 8 are removed. In addition, the inter layer dielectric 3 near the insulators 8 is etched. As a result, the volume of each concave portion H3 increases as compared to its volume before the wet etching. FIG. 17B illustrates the insulators 81 remaining inside and outside the concave portions H3 after the wet etching. The insulators 81 inside the concave portions H3 are called cap portions, and the insulators 81 outside the concave portions H3 are called visor portions. In FIG. 17B, the bottom face of each concave portion H3 has the same shape as the lower faces Sa and Sb of each contact plug 6 illustrated in FIG. 15.

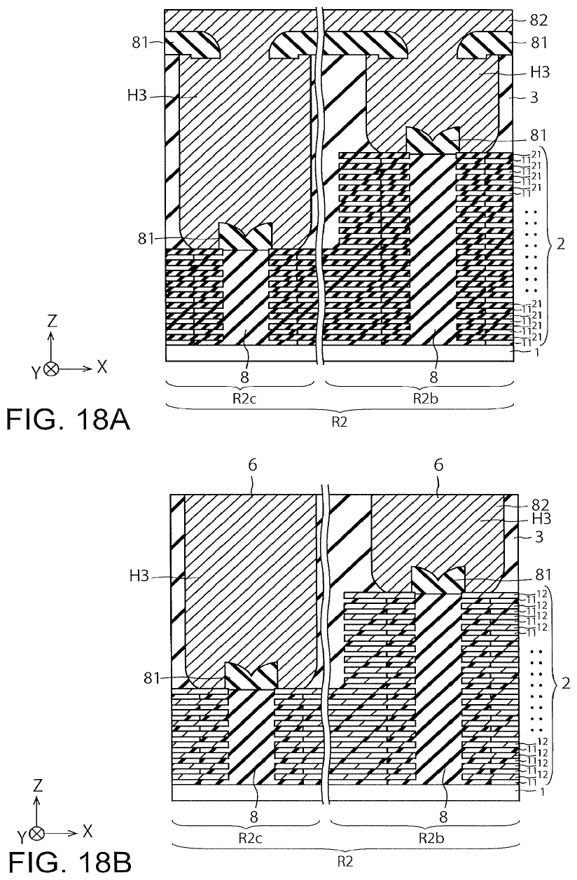

Subsequently, a metal layer 82 is formed inside and outside the concave portions H3 (FIG. 18A). Subsequently, the surface of the metal layer 82 is flattened by CMP (FIG. 18B). As a result, the metal layer 82 and the insulators 81 (visor portions) outside the concave portions H3 are removed, and the metal layer 82 inside the concave portions H3 remains. The metal layer 82 inside the concave portions H3 become the contact plugs 6. The contact plug 6 inside each concave portion H3 is affected by the shape of the bottom face of the corresponding concave portion H3 and formed to have the lower faces Sa and Sb. In the process in FIG. 18B, the sacrifice layers 21 in the stacked film 2 are replaced with the electrode layers 12 (replacement process). As a result, in FIG. 18B, the contact plugs 6 inside the concave portions H3 are formed on the electrode layers 12 and the insulators 81 (cap portions). The replacement process of the present embodiment may be performed by the same method as the replacement process of the first embodiment.

In this manner, the semiconductor device illustrated in FIG. is manufactured.

The insulators 81 and the insulators 8 of the present embodiment are low-etching-rate portions and high-etching-rate portions, respectively. The low-etching-rate portions and the high-etching-rate portions may be formed by forming the insulators 8 through ionic atomic layer deposition (ALD) instead of being formed by reforming the insulators 8. With ionic ALD, insulators 8 to be formed on the side face of an underlayer (such as the source layer 1, the stacked film 2, and the inter layer dielectric 3) and insulators 8 to be formed on the upper face of the underlayer can be formed with different properties. Accordingly, the insulators 8 including the low-etching-rate portions and the high-etching-rate portions can be formed. Specifically, the low-etching-rate portions and the high-etching-rate portions can be formed irrespective of reformation of the insulators 8. In this case, the low-etching-rate portions of the insulators 8 are formed at the positions of the insulators 81 illustrated in FIG. 17A, and the high-etching-rate portions of the insulators 8 are formed at the positions of the insulators 8 illustrated in FIG. 17A.

The low-etching-rate and high-etching-rate portions of the insulators 8 may be formed through ionic deposition other than ionic ALD.

The processes illustrated in FIGS. 18A and 18B will be described below. The insulators 81 (visor portions) outside the concave portions H3 may be removed before the metal layer 82 is formed through the process illustrated in FIG. 18A. This is because the visor portions would otherwise interfere with embedding of the metal layer 82 in the concave portions H3 and voids are potentially formed in the metal layer 82 near the visor portions. The visor portions are removed by, for example, forming a film such as an application film inside and outside the concave portions H3 and flattening the surfaces of the film and the visor portions by CMP. In this case, the film is removed thereafter by etching back such that the insulators 81 (cap portions) inside the concave portions H3 remain. Subsequently, the metal layer 82 is formed inside and outside the concave portions H3 (FIG. 18A).

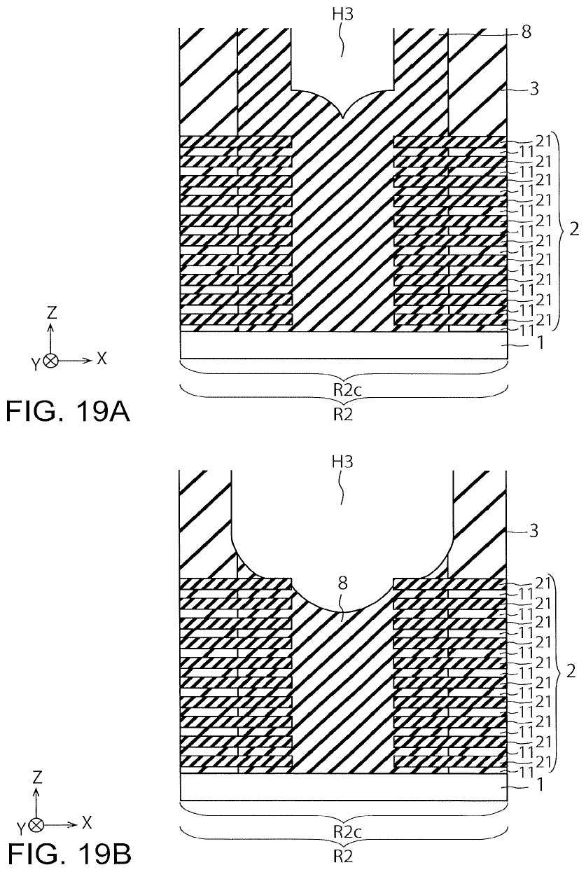

FIGS. 19A and 19B are a cross-sectional view illustrating a method of manufacturing a semiconductor device of a comparative example of the third embodiment.

Similarly to FIG. 16A, FIG. 19A illustrates a process in which the insulators 8 are formed. In the third embodiment, some of the insulators 8 are reformed into the insulators 81 (FIGS. 16B and 17A), and thereafter, the insulators 8 are removed from the side face of the inter layer dielectric 3 (FIG. 17B). However, in the comparative example, the insulators 8 are removed from the side face of the inter layer dielectric 3 without such reformation (FIG. 19B). In this case, the concave portions H3 enlarge to the insulators 8 formed in the stacked film 2 as illustrated in FIG. 19B. As a result, each contact plug 6 formed later in the concave portions H3 not only contacts the topmost electrode layer 12 in the portion R2c but also approaches the next topmost electrode layer 12 in the portion R2c. As a result, breakdown voltage between each contact plug 6 and a non-selection word line decreases.

However, each contact plug 6 of the present embodiment is formed above the corresponding insulator 8 via an insulator 81 as illustrated in FIG. 15. With this configuration, breakdown voltage between each contact plug 6 and a non-selection word line can be improved.

According to the present embodiment, similarly to the first embodiment, the contact plugs 6 can be excellently formed on the electrode layers 12. Specifically, according to the present embodiment, breakdown voltage between each contact plug 6 and a non-selection word line can be improved by forming the contact plugs 6 having shapes different from those of the contact plugs 6 of the first embodiment.

The semiconductor device of the second embodiment may employ the structure of the semiconductor device of the third embodiment instead of employing the structure of the semiconductor device of the first embodiment.

### Fourth Embodiment

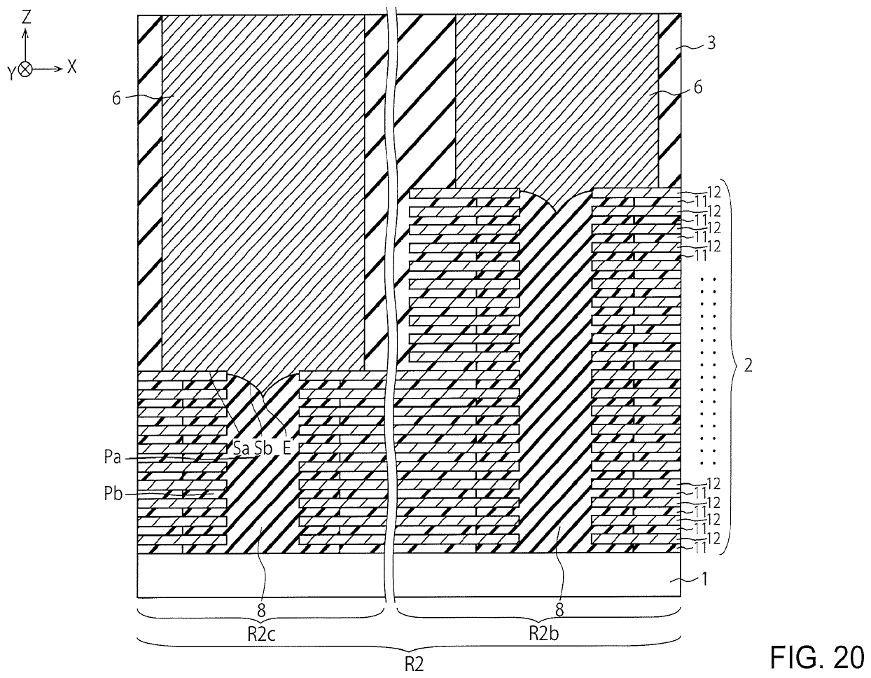

FIG. 20 is a cross-sectional view illustrating the structure of a semiconductor device of a fourth embodiment.

The semiconductor device of the present embodiment (FIG. 20) has the same structure as the semiconductor device of the third embodiment (FIG. 15). However, the semiconductor device of the present embodiment includes no insulators 81. Each contact plug 6 of the present embodiment is formed on the stacked film 2 and the corresponding insulator 8.

Similarly to FIG. 15, FIG. 20 also illustrates the lower faces Sa and Sb of the contact plug 6 positioned on the portion R2c of the step structure portion R2. Although the lower face Sb illustrated in FIG. 15 is positioned higher than the lower face Sa and positioned on the corresponding insulator 81, the lower face Sb illustrated in FIG. 20 is positioned lower than the lower face Sa and positioned on the corresponding insulator 8.

The shape of the lower face Sb illustrated in FIG. 20 is the same as the shape of the lower face Sb illustrated in FIG. 15. The lower face Sb illustrated in FIG. 20 has a shape similar to the side face of a circular cone having the lower end E as an apex, and specifically, has a shape that is concave toward the inside of the circular cone with respect to the side face of the circular cone. In other words, tilt at a point on the lower face Sb is larger as the distance between the point and the lower end E is shorter. This is the same for the other contact plugs 6, for example, the contact plug 6 positioned on the portion R2b of the step structure portion R2. The reason for formation of the contact plugs 6 in such a shape will be described later. Each contact plug 6 of the present embodiment may have a lower face in a shape different from those of the lower faces Sa and Sb.

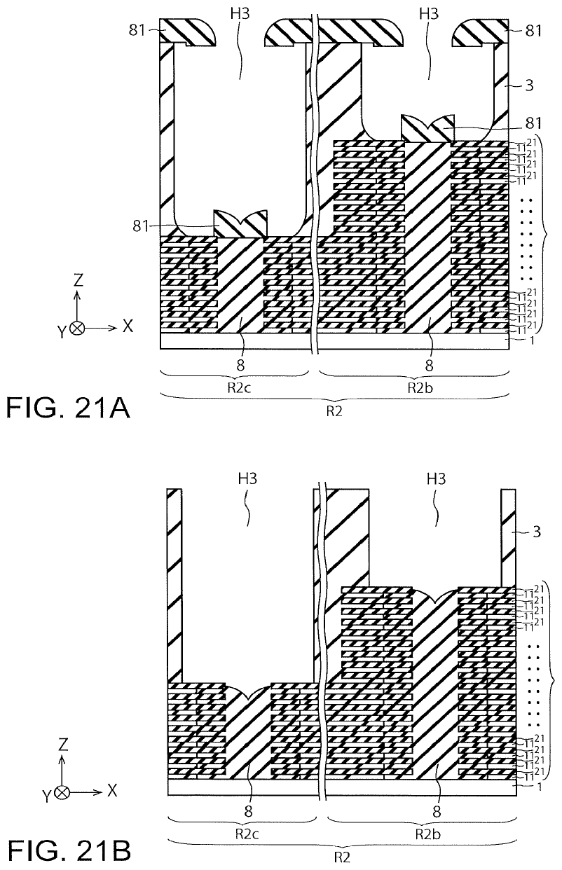

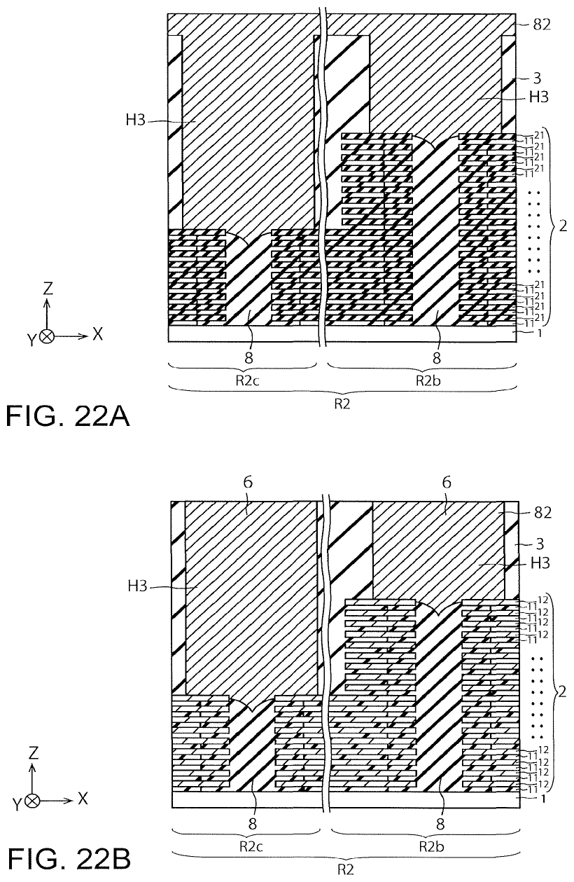

FIGS. 21A to 22B are cross-sectional views illustrating a method of manufacturing the semiconductor device of the fourth embodiment.

FIG. 21A illustrates the same process as the process illustrated in FIG. 17B. Subsequently, in the present embodiment, the insulators 81 (cap portions) inside the concave portions H3 and the insulators 81 (visor portions) outside the concave portions H3 are removed (FIG. 21B). The visor portions are removed by, for example, forming a film such as an application film inside and outside the concave portions H3 and flattening the surfaces of the film and the visor portions by CMP. In this case, the film is removed thereafter by etching back. The etching back is performed so that the cap portions are removed. In this manner, the cap portions and the visor portions are removed. In FIG. 21B, the bottom face of each concave portion H3 has the same shape as the lower faces Sa and Sb of the contact plug 6 illustrated in FIG. 20.

Subsequently, the metal layer 82 is formed inside and outside the concave portions H3 (FIG. 22A). Subsequently, the surface of the metal layer 82 is flattened by CMP (FIG. 22B). As a result, the metal layer 82 outside the concave portions H3 is removed, and the metal layer 82 inside the concave portions H3 remains. The metal layer 82 inside the concave portions H3 becomes the contact plugs 6. The contact plug 6 inside each concave portion H3 is affected by the shape of the bottom face of the concave portion H3 and formed to have the lower faces Sa and Sb. Through the process in FIG. 22B, the sacrifice layers 21 in the stacked film 2 are replaced with the electrode layers 12 (replacement process). As a result, in FIG. 22B, the contact plug 6 inside each concave portion H3 is formed on the electrode layers 12 and the corresponding insulator 8. The replacement process of the present embodiment may be performed by the same method as the replacement process of the first embodiment.

In this manner, the semiconductor device illustrated in FIG. is manufactured.

Similarly to the concave portions H3 illustrated in FIG. 19B for the comparative example of the third embodiment, the concave portions H3 illustrated in FIG. 21B enlarge to the insulators 8 formed in the stacked film 2. However, the bottom face of each concave portion H3 illustrated in FIG. 21B has a shape that is concave toward the inside of a circular cone with respect to the side face of the circular cone although the bottom face of each concave portion H3 illustrated in FIG. 19B has a shape that is convex toward the outside of a circular cone with respect to the side face of the circular cone. As a result, the distance between each contact plug 6 of the present embodiment and the next topmost electrode layer 12 is longer than the distance between each contact plug 6 of the above-described comparative example and the next topmost electrode layer 12. With this configuration, according to the present embodiment, breakdown voltage between each contact plug 6 and a non-selection word line can be improved.

According to the present embodiment, similarly to the first and third embodiments, the contact plugs 6 can be excellently formed on the electrode layers 12. Specifically, according to the present embodiment, breakdown voltage between each contact plug 6 and a non-selection word line can be improved by forming the contact plugs 6 having shapes different from those of the contact plugs 6 of the first and third embodiments.

The semiconductor device of the second embodiment may employ the structure of the semiconductor device of the fourth embodiment instead of employing the structure of the semiconductor device of the first embodiment.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the devices and methods described herein may be made without departing from the spirit of the inventions. The accompanying claims and their equivalents are intended to cover such forms or modifications as would fall within the scope and spirit of the inventions.

1. A semiconductor device comprising:
a stacked film including a plurality of first insulators and a plurality of electrode layers that are alternately stacked in a first direction;
a first plug provided on a first electrode layer among the plurality of electrode layers, and having a tube shape extending in the first direction; and
a second insulator provided in the first plug and the first electrode layer, and having a columnar shape extending in the first direction,
wherein a diameter of a side face of the first plug enclosing the second insulator is larger than a diameter of a side face of the first electrode layer enclosing the second insulator.

2. The device of claim 1, wherein
the stacked film includes a step structure portion having a step shape, and
the first plug is provided on the first electrode layer included in the step structure portion.

3. The device of claim 2, wherein the first electrode layer is a topmost electrode layer in the stacked film below the first plug.

4. The device of claim 1, further comprising a third insulator provided in the stacked film, and positioned below the second insulator.

5. The device of claim 4, wherein the third insulator is formed of a kind of an insulating material that is different from a kind of an insulating material that forms the second insulator.

6. The device of claim 1, further comprising a fourth insulator provided on the stacked film,
wherein the first plug is provided in the fourth insulator.

7. The device of claim 6, wherein the first insulators and the fourth insulator include silicon and oxygen.

8. The device of claim 1, further comprising a fifth insulator provided in the stacked film, having a columnar shape extending in the first direction, and separated from the first plug.

9. The device of claim 8, wherein
the stacked film includes a step structure portion having a step shape, and
the fifth insulator is provided in the step structure portion.

10. The device of claim 1, further comprising:
a charge storage layer provided in the stacked film; and
a semiconductor layer provided in the stacked film via the charge storage layer.

11. A method of manufacturing a semiconductor device, comprising:
forming a stacked film alternately including a plurality of first insulators and a plurality of first films in a first direction;
forming a fourth insulator on the stacked film;
forming a first concave portion in the fourth insulator and the stacked film;
recessing side faces of the first insulators and the fourth insulator with respect to side faces of the first films in the first concave portion;
forming, in the first concave portion, a third insulator that includes a first portion in the stacked film and a second portion on the stacked film;
forming a second insulator in the second portion on the first portion;
removing the second portion after the second insulator is formed, to form a second concave portion between the second insulator and the fourth insulator; and
forming a first plug in the second concave portion.

12. The method of claim 11, further comprising:
removing the plurality of first films, to form a plurality of third concave portions in the stacked film; and
forming a plurality of electrode layers in the plurality of third concave portions.

13. The method of claim 12, wherein the first plug and the plurality of electrode layers are formed of a same metal layer.

14. The method of claim 13, wherein the metal layer includes tungsten (W), aluminum (Al), copper (Cu), titanium (Ti), tantalum (Ta) or ruthenium (Ru).

15. The method of claim 12, wherein the first plug is formed on a first electrode layer among the plurality of electrode layers.

16. The method of claim 15, wherein the first plug and the first electrode layer are formed such that a diameter of a side face of the first plug enclosing the second insulator is larger than a diameter of a side face of the first electrode layer enclosing the second insulator.

17. The method of claim 15, wherein
the stacked film is formed to include a step structure portion having a step shape,
the first plug is formed on the first electrode layer that is included in the step structure portion, and
the first electrode layer is a topmost electrode layer in the stacked film below the first plug.

18. The method of claim 11, wherein the first concave portion is formed to penetrate through the stacked film.

19. The method of claim 11, wherein the side faces of the first insulators and the fourth insulator are recessed with respect to the side faces of the first films by wet etching.

20. The method of claim 11, wherein the first insulators and the fourth insulator include silicon and oxygen, and the first films include silicon and nitrogen.
